(19) United States
(12) Patent Application Publication
(10) Pub. No.: US 2024/0170620 A1
(43) Pub. Date: May 23, 2024

(54) DISPLAY PANEL

(71) Applicant: Samsung Display Co., LTD., Yongin-si (KR)

(72) Inventors: Ji Wook MOON, Suwon-si (KR); Byung Choon YANG, Seoul (KR)

(73) Assignee: Samsung Display Co., LTD., Yongin-si (KR)

(21) Appl. No.: 17/993,014

(22) Filed: Nov. 23, 2022

(30) Foreign Application Priority Data
Feb. 16, 2022 (KR) 10-2022-0020292

(51) Int. Cl. H01L 33/50; H01L 27/15; H01L 33/38; H01L 33/46; H01L 33/62

(52) U.S. Cl. CPC H01L 33/504; H01L 27/156; H01L 33/387; H01L 33/46; H01L 33/505; H01L 33/62

(57) ABSTRACT

A display panel includes a plurality of light emitting members disposed on a substrate, each disposed on a plurality of emission areas of the substrate and a bank. Each of the plurality of light emitting members corresponds to one of two or more different colors. One of the plurality of light emitting members includes a light emitting device, a first color conversion layer disposed on the light emitting device and including phosphors converting a portion of light of the light emitting device, a light scattering layer disposed on the first color conversion layer, and a second color conversion layer disposed on the light scattering layer and including quantum dots converting still another portion of the light of the light emitting device or light scattered by the light scattering layer into a wavelength region of a color corresponding to the one light emitting member.

### CROSS-REFERENCE TO RELATED APPLICATION

This application claims priority to and benefits of Korean Patent Application No. 10-2022-0020292 under 35 U.S.C. § 119, filed on Feb. 16, 2022, in the Korean Intellectual Property Office (KIPO), the entire contents of which are incorporated herein by reference.

### BACKGROUND

### 1. Technical Field

The disclosure relates to a display panel.

### 2. Description of the Related Art

As the information society develops, the demand for display devices for displaying images has increased and diversified. For example, display devices have been applied to various electronic devices such as smartphones, digital cameras, laptop computers, navigation devices, and smart televisions.

The display devices may be flat panel display devices such as liquid crystal displays (LCDs), field emission displays (FEDs), or light emitting displays (LEDs).

The light emitting display may be implemented as an organic light emitting display including organic light emitting diode elements, an inorganic light emitting display including inorganic semiconductor elements, a micro light emitting display including micro light emitting diode elements, and the like, according to light emitting devices emitting light.

Since the light emitting devices emit light of a wavelength region corresponding to a single color, the light emitting display may display a color image by including a color conversion layer that converts the wavelength region of the light emitted from the light emitting diode elements.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Aspects of the disclosure provide a display panel capable of reducing damage to color conversion layers due to heat generated by light emitting devices.

However, aspects of the disclosure are not restricted to those set forth herein. The above and other aspects of the disclosure will become more apparent to one of ordinary skill in the art to which the disclosure pertains by referencing the detailed description of the disclosure given below.

According to an embodiment, a display panel may include a substrate including emission areas, light emitting members disposed on the substrate, each of the light emitting members disposed in the emission areas, and a bank disposed on the substrate in a boundary between adjacent ones of the emission areas. Each of the light emitting members may correspond to one of two or more different colors. Any one of the light emitting members may include a light emitting device disposed on the substrate and emitting light, a first color conversion layer disposed on the light emitting device and including phosphors converting a portion of light of the light emitting device into a wavelength region higher than a wavelength region of the light of the light emitting device, a light scattering layer disposed on the first color conversion layer and scattering another portion of the light of the light emitting device or light of the first color conversion layer, and a second color conversion layer disposed on the light scattering layer and including quantum dots converting still another portion of the light of the light emitting device or the another portion of the light scattered by the light scattering layer into a wavelength region of the one of two or more different colors which the one of the light emitting members corresponds.

The light emitting members may include a first light emitting member emitting light of a first color, a second light emitting member emitting light of a second color of which a wavelength region is lower than a wavelength region of the first color, and a third light emitting member emitting light of a third color of which a wavelength region is lower than the wavelength region of the second color.

Each of the first light emitting member, the second light emitting member, and the third light emitting member may include the first color conversion layer, the light scattering layer, and the second color conversion layer. The light emitting device of each of the light emitting members may emit light of a wavelength region lower than the wavelength region of the third color. The first color conversion layer of the third light emitting member may include the phosphors corresponding to the wavelength region of the third color. The second color conversion layer of the first light emitting member may include first quantum dots corresponding to the wavelength region of the first color. The second color conversion layer of the second light emitting member may include second quantum dots corresponding to the wavelength region of the second color. The second color conversion layer of the third light emitting member may include third quantum dots corresponding to the wavelength region of the third color. The phosphor corresponding to the wavelength region of the third color may include BaAlMg₁₀O₁₇:Eu²⁺.

The first color conversion layer of the first light emitting member and the first color conversion layer of the second light emitting member may include the phosphors corresponding to a wavelength region between the first color and the second color. The phosphors corresponding to the wavelength region between the first color and the second color may include (Y, Gd)₃Al₅O₁₂:Ce³⁺ or (La, Y)₃Si₆N₁₁:Ce³⁺.

The first color conversion layer of the first light emitting member may include first phosphors corresponding to the wavelength region of the first color. The first color conversion layer of the second light emitting member may include second phosphors corresponding to the wavelength region of the second color. The first phosphors may include at least one selected from the group of (Sr, Ca)AlSiN₃:Eu²⁺, K₂(Si, Ge, Ti)F₆:Mn⁴⁺, Mg₄GeO₃F:Mn⁴⁺, or 3.5MgO·0.5MgF₂·GeO₂:Mn⁴⁺. The second phosphors may include at least one selected from the group of Beta-SiAlON:Eu²⁺, SrGa₂S₄:Eu²⁺, BaAlMg₁₀O₁₇:Eu²⁺, Mn²⁺, (Sr, Ba, Mg)₂SiO₄:Eu²⁺, and (Lu,Y)₃(Al, Ga)₅O₁₂:Ce³⁺.

The first light emitting member and the second light emitting member each may include the first color conversion layer, the light scattering layer, and the second color conversion layer. The second color conversion layer of the first light emitting member may include first quantum dots corresponding to the wavelength region of the first color. The second color conversion layer of the second light emitting member may include second quantum dots corresponding to the wavelength region of the second color. The light emitting device of the third light emitting member may emit light of the wavelength region of the third color. The third light emitting member may include a filling layer disposed on the light emitting device.

The filling layer of the third light emitting member may include scatterers scattering the light of the light emitting device.

The first color conversion layer of the first light emitting member and the first color conversion layer of the second light emitting member each may include phosphors corresponding to a wavelength region between the first color and the second color. The phosphors corresponding to the wavelength region between the first color and the second color may include (Y, Gd)₃Al₅O₁₂:Ce³⁺ or (La, Y)₃Si₆N₁₁:Ce³⁺.

The first color conversion layer of the first light emitting member may include first phosphors corresponding to the wavelength region of the first color. The first color conversion layer of the second light emitting member may include second phosphors corresponding to the wavelength region of the second color. The first phosphors may include at least one selected from the group of (Sr, Ca)AlSiN₃:Eu²⁺, K₂(Si, Ge, Ti)F₆:Mn⁴⁺, Mg₄GeO₃F:Mn⁴⁺, and 3.5MgO·0.5MgF₂·GeO₂:Mn⁴⁺, and the second phosphors may include at least one selected from the group of Beta-SiAlON:Eu²⁺, SrGa₂S₄:EU 2+, BaAlMg₁₀O₁₇:Eu²⁺, Mn²⁺, and (Lu,Y)₃(Al, Ga)₅O₁₂:Ce³⁺.

The light emitting device of the first light emitting member and the light emitting device of the second light emitting member each may emit light of a wavelength region lower than the wavelength region of the third color.

The light emitting device of the first light emitting member may emit light of a wavelength region lower than the wavelength region of the third color. The light emitting device of the second light emitting member may emit light of a wavelength region of the third color.

The first color conversion layer of the second light emitting member may include phosphors converting the light of the wavelength region of the third color emitted from the light emitting device into light of the wavelength region of the second color. The phosphors of the first color conversion layer of the second light emitting member may include Beta-SiAlON:Eu²⁺.

The light emitting device of the first light emitting member and the light emitting device of the second light emitting member each may emit light of a wavelength region of the third color.

The first color conversion layer of the first light emitting member may include first phosphors converting the light of the wavelength region of the third color emitted from the light emitting device into light of the wavelength region of the first color. The first color conversion layer of the second light emitting member may include second phosphors converting the light of the wavelength region of the third color emitted from the light emitting device into light of the wavelength region of the second color. The first phosphors may include (Sr, Ca)AlSiN₃:Eu²⁺ or K₂(Si, Ge, Ti)F₆:Mn⁴⁺. The second phosphors may include at least one selected from the group of Beta-SiAlON:Eu²⁺, SrGa₂S₄:Eu²⁺, (Lu, Y)₃(Al, Ga)₅O₁₂:Ce³⁺, BaAlMg₁₀O₁₇:Eu²⁺, Mn⁴⁺, and (Sr, Ba, Mg)₂SiO₄:Eu²⁺.

The display panel may further include a protective layer disposed on the light emitting members and the bank, and a color filter layer disposed on the protective layer. The color filter layer may include a first color filter corresponding to the first light emitting member, a second color filter corresponding to the second light emitting member, a third color filter corresponding to the third light, and a light blocking member corresponding to the bank.

The protective layer may include an inorganic insulating material of SiO₂₋ₓ or SiO₂, and x may be 0, 1, or 2.

The display panel may further include a transistor array disposed on the substrate. The transistor array may include at least one thin film transistor disposed on the substrate in each of the emission areas, a common line disposed on the substrate and extending in a direction corresponding to arrangement directions of the emission areas, a planarization layer disposed on the at least one thin film transistor and the common line of each of the emission areas, a pixel electrode disposed on the planarization layer in each of the emission areas, and a common electrode disposed on the planarization layer in each of the emission areas, spaced apart from the pixel electrode, and electrically connected to the common line. The bank may be disposed on the planarization layer. The pixel electrode may be electrically connected to at least one of the at least one thin film transistor, and a first electrode of the light emitting device may be disposed on the pixel electrode, may face the pixel electrode, and may be electrically connected to the pixel electrode in each of the emission areas.

The light emitting device may include a second electrode facing the first electrode. The second electrode of the light emitting device may be electrically connected to the common electrode through a wire.

The light emitting device may include a second electrode disposed parallel to the first electrode. The second electrode of the light emitting device may face the common electrode, and may be electrically connected to the common electrode through an extension electrode. The extension electrode may be disposed between the common electrode and the second electrode.

The light scattering layer may include scatterers. A diameter of each of the scatterer may be in a range of about 10 nm to about 500 nm. The scatterer may include at least one selected from the group of titanium oxide (TiO₂), silicon oxide (SiO₂), aluminum oxide (Al₂O₃), and zirconium oxide (ZrO₂).

The display panel may further include a reflective layer disposed on an edge of each of the emission areas and covering a sidewall of the bank.

The reflective layer may include scatterers including at least one selected from the group of titanium oxide (TiO₂), silicon oxide (SiO₂), aluminum oxide (Al₂O₃), zirconium oxide (ZrO₂), and boron nitride (BN).

A display panel according to embodiments may include light emitting members each disposed in a plurality of emission areas. Any one of the light emitting members may include a light emitting device, a first color conversion layer disposed on the light emitting device and including phosphors converting a portion of light of the light emitting device into a wavelength region higher than a wavelength region of the light of the light emitting device, a light scattering layer disposed on the first color conversion layer and scattering another portion of the light of the light emitting device, and a second color conversion layer disposed on the light scattering layer and including quantum dots converting still another portion of the light of the light emitting device into a wavelength region of a color corresponding to the one of the light emitting members.

As described above, a light emitting member may include the first color conversion layer disposed between the light emitting device and the second color conversion layer and including the phosphors absorbing a portion of the light of the light emitting device, and thus, a degree of which the quantum dots of the second color conversion layers are exposed to driving heat of the light emitting device or a light source may be decreased. Accordingly, damage to the quantum dots of the second color conversion layer due to the driving heat of the light emitting device or the light source may be reduced.

Therefore, color purity may be improved by the second color conversion layer including the quantum dots, and device reliability and lifespan may be improved.

The effects of the disclosure are not limited to the aforementioned effects, and various other effects are included in the specification.

### BRIEF DESCRIPTION OF THE DRAWINGS

The above and other aspects and features of the disclosure will become more apparent by describing in detail embodiments thereof with reference to the attached drawings, in which:

FIG. 1 is a plan view illustrating a display panel according to an embodiment;

FIG. 2 is a view illustrating portion A of FIG. 1 in detail;

FIG. 3 is a view illustrating portion B of FIG. 2 in detail;

FIG. 4 is a view illustrating a pixel electrode, a common electrode, and a light emitting device of a transistor array corresponding to portion B of FIG. 2;

FIG. 5 is a schematic diagram an equivalent circuit of any one emission area of FIG. 2;

FIG. 6 is a schematic cross-sectional view taken along line C-C′ of FIG. 4 according to a first embodiment;

FIG. 7 is a view illustrating a light emitting device of FIG. 6 in detail;

FIG. 8 is a schematic cross-sectional view taken along line C-C′ of FIG. 4 according to a second embodiment;

FIG. 9 is a schematic cross-sectional view taken along line C-C′ of FIG. 4 according to a third embodiment;

FIG. 10 is a schematic cross-sectional view taken along line C-C′ of FIG. 4 according to a fourth embodiment;

FIG. 11 is a schematic cross-sectional view taken along line C-C′ of FIG. 4 according to a fifth embodiment;

FIG. 12 is a schematic cross-sectional view taken along line C-C′ of FIG. 4 according to a sixth embodiment;

FIG. 13 is a schematic cross-sectional view taken along line C-C′ of FIG. 4 according to a seventh embodiment;

FIG. 14 is a schematic cross-sectional view taken along line C-C′ of FIG. 4 according to an eighth embodiment;

FIG. 15 is a schematic cross-sectional view taken along line C-C′ of FIG. 4 according to a ninth embodiment; and

FIG. 16 is a schematic cross-sectional view taken along line C-C′ of FIG. 4 according to a tenth embodiment.

### DETAILED DESCRIPTION OF THE EMBODIMENTS

The embodiments will now be described more fully hereinafter with reference to the accompanying drawings. The embodiments may, however, be provided in different forms and should not be construed as limiting. The same reference numbers indicate the same components throughout the disclosure. In the accompanying figures, the thickness of layers and regions may be exaggerated for clarity.

Some of the parts which are not associated with the description may not be provided in order to describe embodiments of the disclosure.

It will also be understood that when a layer is referred to as being “on” another layer or substrate, it can be directly on the other layer or substrate, or intervening layers may also be present. In contrast, when an element is referred to as being “directly on” another element, there may be no intervening elements present.

The phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. The term “overlap” may include layer, stack, face or facing, extending over, covering or partly covering, or any other suitable term as would be appreciated and understood by those of ordinary skill in the art. The expression “not overlap” may include meaning such as “apart from”, “set aside from”, or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below”, for example, can encompass both an orientation of above and below. Furthermore, the apparatus may be otherwise oriented (e.g., rotated 90 degrees or at other orientations), and, as such, the spatially relative descriptors used herein interpreted accordingly.

When an element is referred to as being “connected” or “coupled” to another element, the element may be “directly connected” or “directly coupled” to another element, or “electrically connected” or “electrically coupled” to another element with one or more intervening elements interposed therebetween. It will be further understood that when the terms “comprises”, “comprising”, “has”, “have”, “having”, “includes”, and/or “including” are used, they may specify the presence of stated features, integers, steps, operations, elements and/or components, but do not preclude the presence or addition of other features, integers, steps, operations, elements, components, and/or any combination thereof.

It will be understood that, although the terms “first”, “second”, “third”, or the like may be used herein to describe various elements, these elements should not be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the teachings herein.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within ±30%, 20%, 10%, 5% of the stated value.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.” In the specification and the claims, the phrase “at least one of” is intended to include the meaning of “at least one selected from the group of” for the purpose of its meaning and interpretation. For example, “at least one of A and B” may be understood to mean “A, B, or A and B.”

Unless otherwise defined or implied, all terms used herein (including technical and scientific terms) have the same meaning as commonly understood by those skilled in the art to which this disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

Hereinafter, embodiments will be described with reference to the accompanying drawings.

In the following drawings, a first direction DR1 and a second direction DR2 may correspond to a plane of a display panel 100, and a third direction DR3 may correspond to a thickness of the display panel 100. In an embodiment, the first direction DR1 may be a horizontal direction (transverse direction) in the plane of the display panel 100, the second direction DR2 may be a vertical direction (longitudinal direction) in the plane of the display panel 100, and the third direction DR3 may be a thickness direction of the display panel 100.

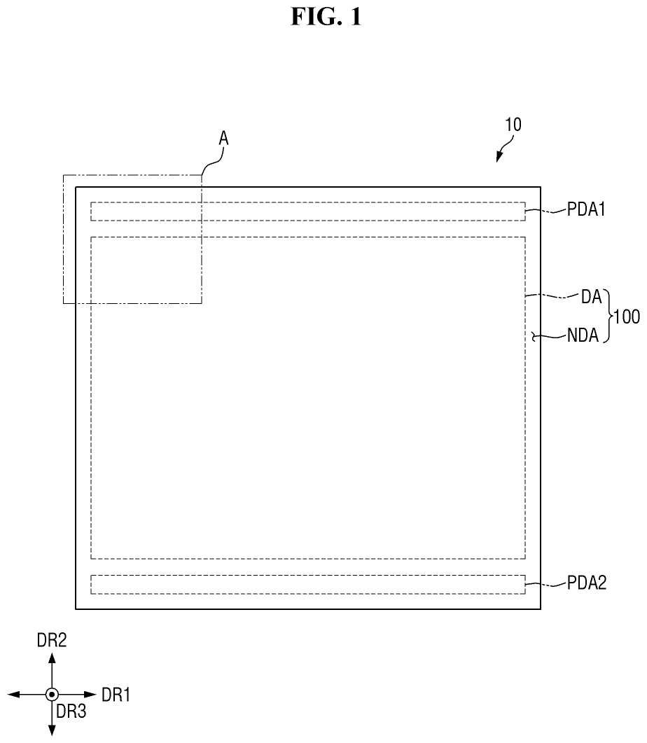

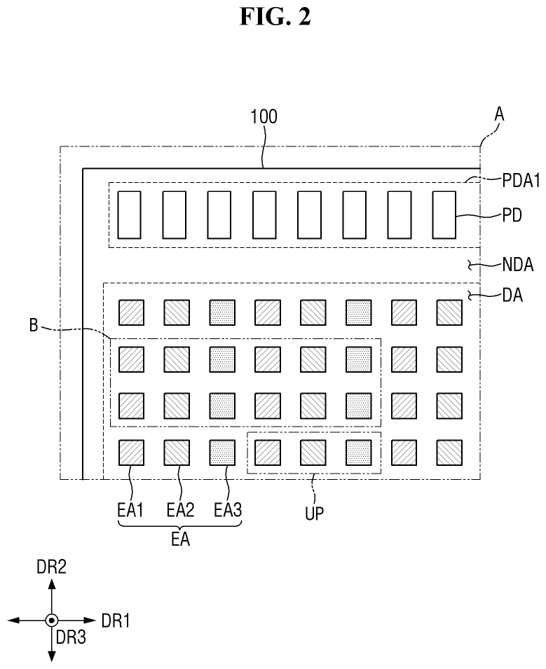

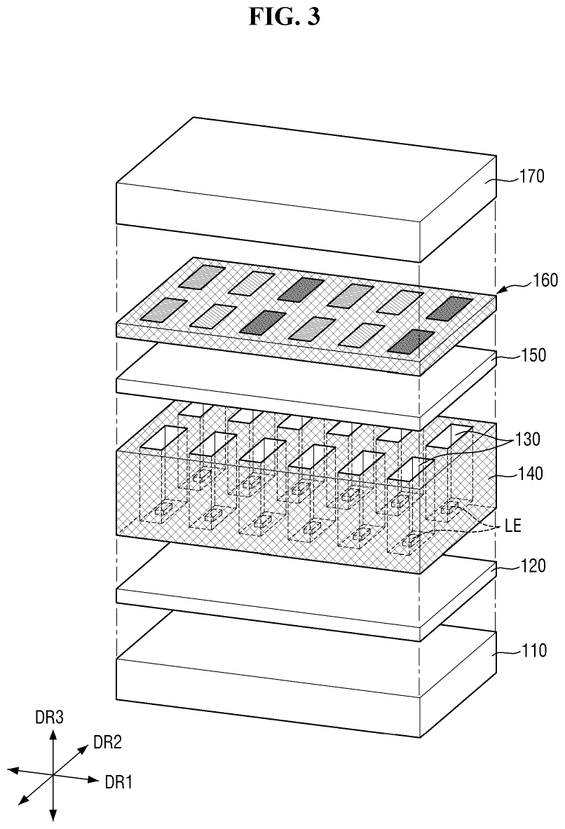

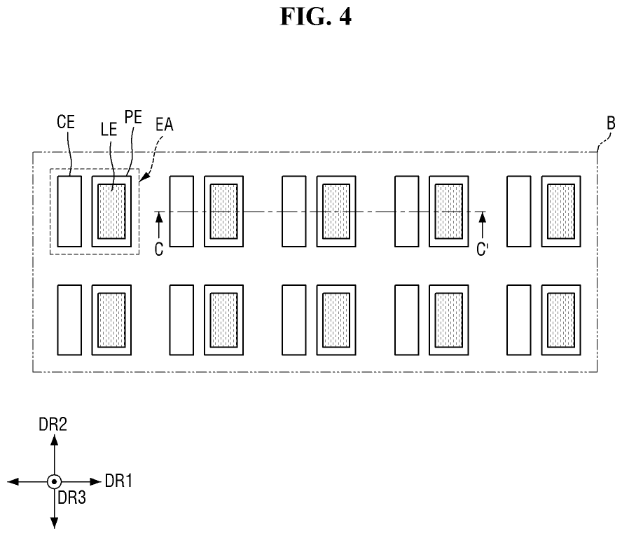

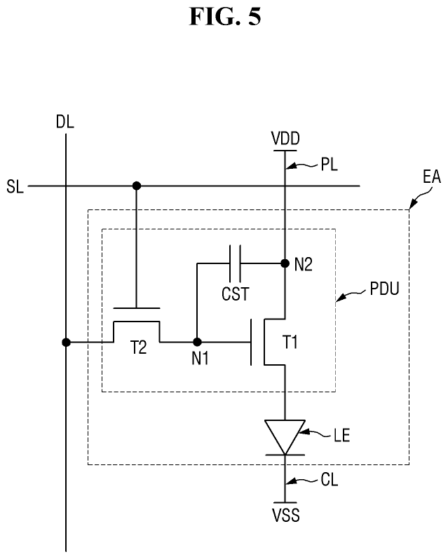

FIG. 1 is a plan view illustrating a display panel according to an embodiment. FIG. 2 is a view illustrating portion A of FIG. 1 in detail. FIG. 3 is a view illustrating portion B of FIG. 2 in detail. FIG. 4 is a view illustrating a pixel electrode, a common electrode, and a light emitting device of a transistor array corresponding to portion B of FIG. 2. FIG. 5 is a schematic diagram an equivalent circuit of any one emission area of FIG. 2.

Referring to FIG. 1, a display device 10 according to an embodiment may include a display panel 100 having a flat panel form.

The display device 10 may be a device that displays a moving image or a still image, and may be used as a display screen of each of various products such as televisions, laptop computers, monitors, billboards, and Internet of Things (JOT) devices as well as portable electronic devices such as mobile phones, smartphones, tablet personal computers (PCs), smart watches, watch phones, mobile communication terminals, electronic notebooks, electronic books, portable multimedia players (PMPs), navigation devices, and ultra mobile PCs (UMPCs).

The display panel 100 may include a display area DA emitting light for displaying an image, and non-display areas NDA, which are surrounding areas of the display area DA.

The display area DA may have a shape such as a polygonal shape such as a rectangular shape or a circular shape in a plan view. In an embodiment, the display area DA may have a rectangular shape, in a plan view, having short sides in the first direction DR1 and long sides in the second direction DR2 crossing the first direction DR1.

In the display area DA having the rectangular shape, a contact point between the short side in the first direction DR1 and the long side in the second direction DR2 may form a right-angled corner. In another embodiment, a contact point between the short side in the first direction DR1 and the long side in the second direction DR2 may form a corner having a curved shape with a predetermined (or selectable) curvature.

The display area DA may correspond to most of the center of a light emitting surface of the display panel 100, and may be surrounded by the non-display areas NDA.

The non-display areas NDA may correspond to edges of the light emitting surface of the display panel 100. The non-display areas NDA may include a first pad area PDA1 and a second pad area PDA2 each adjacent to both sides in the second direction DR2 among the edges of the display area DA. However, this is only an example, and the non-display areas NDA may include only one of the first pad area PDA1 and the second pad area PDA2.

Referring to FIG. 2, each of the first pad area PDA1 and the second pad area PDA2 (not shown in FIG. 2) may include multiple signal pads PD to which an external circuit board (not illustrated) supplying signals or voltages for driving the display panel 100 is electrically connected.

For example, the signal pads PD arranged in the first direction DR1 may be disposed in each of the first pad area PDA1 and the second pad area PDA2.

The display area DA may include multiple emission areas EA arranged in the first direction DR1 and the second direction DR2 and spaced apart from each other.

According to an embodiment, each of the emission areas EA may have a width of several to several tens of nanometers.

Each of the emission area EA may emit light of any one of two or more different colors.

In an embodiment, the emission areas EA may include first emission areas EA1 emitting light of a wavelength region corresponding to a first color, second emission areas EA2 emitting light of a wavelength region corresponding to a second color, which has a wavelength region lower than that of the first color, and third emission areas EA3 emitting light of a wavelength region corresponding to a third color, which has a wavelength region lower than that of the second color. The first color, the second color, and the third color may be red, green, and blue, respectively.

A unit pixel UP, which is a basic unit for displaying various colors, may include a first emission area EA1, a second emission area EA2, and a third emission area EA3 adjacent to each other and emitting light of different colors.

However, the embodiment in FIG. 2 is only an example, and each of the emission areas EA may emit any one of red light, green light, blue light, and white light, and the unit pixel UP may include four emission areas adjacent to each other and emitting red light, green light, blue light, and white light.

Referring to FIG. 3, the display panel 100 of the display device 10 according to an embodiment may include a substrate 110, a transistor array 120 disposed on the substrate 110, multiple light emitting members 130 and a partition wall member or bank 140 disposed on the transistor array 120, a protective layer 150 disposed on the light emitting members 130 and the bank 140, a color filter layer 160 disposed on the protective layer 150, and a transparent protective substrate 170 disposed on the color filter layer 160.

The substrate 110 may be provided in a form of a rigid flat plate. In another embodiment, the substrate 110 may be provided in a form of a flexible flat plate that may be deformed, for example, bent, folded, or rolled.

The substrate 110 may include an insulating material such as glass, quartz, or a polymer resin. The polymer resin may include polyethersulphone (PES), polyacrylate (PA), polyarylate (PAR), polyetherimide (PEI), polyethylene naphthalate (PEN), polyethylene terepthalate (PET), polyphenylene sulfide (PPS), polyallylate, polyimide (PI), polycarbonate (PC), cellulose triacetate (TAC), cellulose acetate propionate (CAP), or combinations thereof.

In another embodiment, the substrate 110 may include a metal material.

The substrate 110 may support the transistor array 120, the light emitting members 130, the bank 140, the color filter layer 160, and the like.

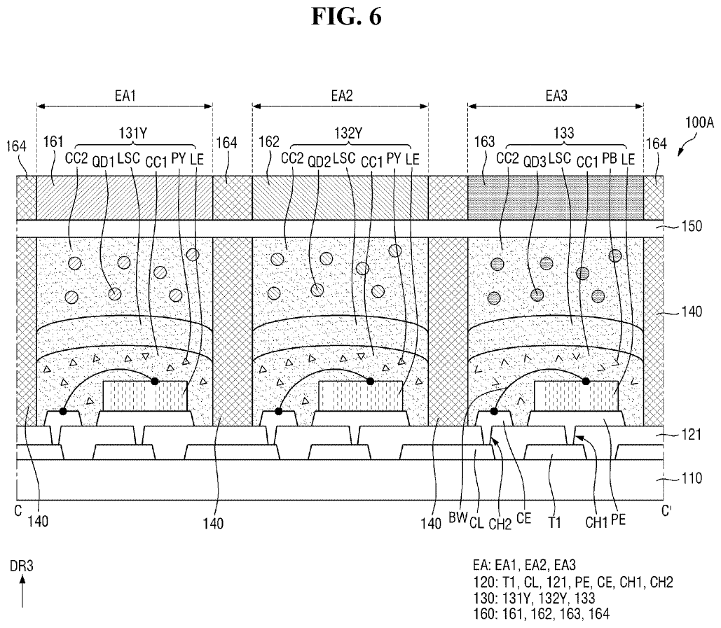

The transistor array 120 may include at least one thin film transistors T1 or T2 (see FIG. 5) corresponding to each of the emission areas EA, a common line CL (see FIG. 5) extending in a direction in the display area DA, a planarization layer 121 (see FIG. 6) covering at least one thin film transistors and the common line CL, multiple pixel electrodes PE disposed on the planarization layer 121 and corresponding to the emission areas EA, and multiple common electrodes CE disposed on the planarization layer 121, corresponding to the emission areas EA, and spaced apart from the pixel electrodes PE.

The transistor array 120 will be described later with reference to FIGS. 4 and 5.

The multiple light emitting members 130 may be disposed on the substrate 110, and correspond to the multiple emission areas EA, respectively.

Each of the light emitting members 130 may include a light emitting device LE emitting light.

The light emitting members 130 may include first light emitting members corresponding to the first emission areas EA1 emitting light of a first color, second light emitting members corresponding to the second emission areas EA2 emitting light of a second color, and third light emitting members corresponding to the third emission areas EA3 emitting light of a third color.

The bank 140 may correspond to a boundary between the emission areas EA. For example, the bank 140 may define each of the emission areas EA, and may be disposed to surround each of the light emitting members 130.

The bank 140 may include a material absorbing light or a material reflecting light. In an embodiment, the bank 140 may include a light-absorbing black matrix.

The protective layer 150 may be disposed on the light emitting members 130 and the bank 140, and may seal each of the light emitting members 130.

The protective layer 150 may include an inorganic insulating material. In an embodiment, the protective layer 150 may include an inorganic insulating material such as SiOₓ. However, this is only an example, and the protective layer 150 may include any material having light-transmitting properties and adhesive properties.

The color filter layer 160 may include first color filters corresponding to the first emission areas EA1 emitting light of the first color, second color filters corresponding to the second emission areas EA2 emitting light of the second color, and third color filters corresponding to the third emission areas EA3 emitting light of the third color.

The first color filter may include a dye or a pigment selectively transmitting the light of the wavelength region corresponding to the first color.

The second color filter may include a dye or a pigment selectively transmitting the light of the wavelength region corresponding to the second color.

The third color filter may include a dye or a pigment selectively transmitting the light of the wavelength region corresponding to the third color.

In case that the emission areas EA also include emission areas emitting white light, the color filter layer 160 may further include color filters corresponding to the emission areas emitting the white light and made of a transparent material.

The transparent protective substrate 170 may be attached on the color filter layer 160 through an adhesive layer (not illustrated).

The transparent protective substrate 170 may include a glass material including SiO₂ as a main component. In another embodiment, the transparent protective substrate 170 may include any plastic material, such as polyethersulfone (PES), polyacrylate (PAR), polyetherimide (PEI), polyethylene naphthalate (PEN), polyethylene terephthalate (PET), polyphenylene sulfide (PPS), polyallylate, polyimide, polycarbonate (PC), cellulose triacetate (TAC), and cellulose acetate propionate (CAP).

Referring to FIG. 4, the display panel 100 may include multiple light emitting devices LE each corresponding to the emission areas EA.

In each of the emission areas EA, the light emitting device LE may be electrically connected between the pixel electrode PE and the common electrode CE.

In an embodiment, each of the emission areas EA may include a pixel electrode PE and a common electrode CE spaced apart from each other.

The light emitting device LE of each of the emission areas EA may include a first electrode disposed on the pixel electrode PE and electrically connected to the pixel electrode PE and a second electrode electrically connected to the common electrode CE.

In an embodiment, in case that the light emitting device LE is a vertical-type light emitting device including first and second electrodes facing each other, the first electrode of the light emitting device LE may directly contact and electrically connected to the pixel electrode PE, and the second electrode of the light emitting device LE may be electrically connected to the common electrode CE through a wire (not illustrated).

In another embodiment, in case that the light emitting device LE is a lateral-type light emitting device including a first electrode and a second electrode disposed in parallel with each other on surfaces facing the pixel electrode PE, the first electrode and the second electrode of the light emitting device LE may be electrically connected to the pixel electrode PE and the common electrode CE, respectively, through respective bonding wires.

In another embodiment, in case that the light emitting device LE is a flip-type light emitting device including a first electrode and a second electrode disposed in parallel with each other on surfaces facing the pixel electrode PE, the first electrode and the second electrode of the light emitting device LE may contact and electrically connected to the pixel electrode PE and the common electrode CE that they face, respectively.

Hereinafter, a case where the display panel 100 includes a vertical-type light emitting devices LE will be described for convenience of explanation, but this is only an example. For example, the display panel 100 according to another embodiment may include a lateral-type light emitting devices or a flip-type light emitting devices LE rather than the vertical-type light emitting devices.

Referring to FIG. 5, the transistor array 120 (see FIG. 3) of the display panel 100 may include multiple pixel driving units PDU each corresponding to the emission areas EA and each electrically connected to the light emitting devices LE of the emission areas EA.

Each of the pixel driving units PDU may include at least one thin film transistors T1 or T2 (see FIG. 5).

For example, the transistor array 120 of the display panel 100 may include at least one thin film transistors T1 or T2 (see FIG. 5) corresponding to each of the emission areas EA.

Each of the emission areas EA may include a light emitting device LE and a pixel driving unit PDU for driving a light emitting device LE.

In an embodiment, as illustrated in FIG. 5, the pixel driving unit PDU may include a first thin film transistor T1 electrically connected to the light emitting device LE, a second thin film transistor T2 electrically connected to the first thin film transistor T1, and a storage capacitor CST.

The first thin film transistor T1 may be electrically connected to the light emitting device LE in series between a power line PL supplying first driving power VDD and a common line CL supplying second driving power VSS having a voltage level lower than that of the first driving power VDD.

For example, a first electrode of the first thin film transistor T1 may be electrically connected to the power line PL, and a second electrode of the first thin film transistor T1 may be electrically connected to an anode electrode of the light emitting device LE.

A cathode electrode of the light emitting device LE may be electrically connected to the common line CL.

The second thin film transistor T2 may be electrically connected between a gate electrode of the first thin film transistor T1 and a data line DL supplying a data signal to each emission area EA. A gate electrode of the second thin film transistor T2 may be electrically connected to a scan line SL supplying a scan signal for selecting whether or not to write the data signal.

The storage capacitor CST may be electrically connected between a first node N1 and a second node N2. The first node N1 may be a contact point between the gate electrode of the first thin film transistor T1 and the second thin film transistor T2, and the second node N2 may be a contact point between the first thin film transistor T1 and the power line PL. For example, the storage capacitor CST may be electrically connected between the gate electrode and the first electrode of the first thin film transistor T1.

In case that the second thin film transistor T2 is turned on based on the scan signal of the scan line SL, the data signal of the data line DL may be supplied to the gate electrode of the first thin film transistor T1 and the storage capacitor CST through the turned-on second thin film transistor T2. Accordingly, the first thin film transistor T1 may be turned on based on the data signal, and a driving current corresponding to the data signal may be supplied to the light emitting device LE through the turned-on first thin film transistor T1. The turn-on of the first thin film transistor T1 may be maintained based on a voltage charged in the storage capacitor CST.

Display panels 100 according to embodiments will be described.

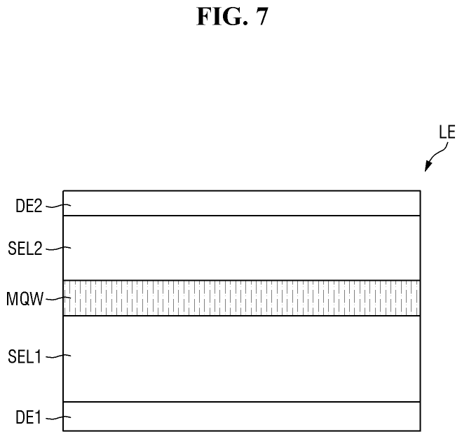

FIG. 6 is a schematic cross-sectional view taken along line C-C′ of FIG. 4 according to a first embodiment. FIG. 7 is a view illustrating a light emitting device of FIG. 6 in detail.

Referring to FIG. 6, a display panel 100A according to a first embodiment may include a substrate 110 including multiple emission areas EA, multiple light emitting members 130 disposed on the substrate 110, each corresponding to the emission areas EA, and a partition wall member or bank 140 disposed on the substrate 110 and corresponding to a boundary between the emission areas EA.

Each of the light emitting members 130 may correspond to any one of two or more different colors.

A light emitting member corresponding to any one color among the light emitting members 130 may include a light emitting device LE disposed on the substrate 110, a first color conversion layer CC1 covering the light emitting device LE and including phosphors (e.g., phosphors of yellow PY or phosphors of blue PB) converting a portion of light of the light emitting device LE into a wavelength region higher than that of the light of the light emitting device LE, a light scattering layer LSC covering the first color conversion layer CC1 and scattering another portion of the light of the light emitting device LE or the light of the first color conversion layer CC1, and a second color conversion layer CC2 covering the light scattering layer LSC and including quantum dots QD1, QD2, or QD3 converting still another portion of the light of the light emitting device LE or the light scattered by the light scattering layer LSC into a wavelength region of any one color.

The light emitting members 130 may include first light emitting members 131Y corresponding to the first emission areas EA1 emitting light of the first color, second light emitting members 132Y corresponding to the second emission areas EA2 emitting light of the second color of which a wavelength region is lower than that of the first color, and third light emitting members 133 corresponding to the third emission areas EA3 emitting light of the third color of which a wavelength region is lower than that of the second color.

In an embodiment, the first color may be red corresponding to a wavelength region of approximately 600 nm to approximately 750 nm.

The second color may be green corresponding to a wavelength region of approximately 480 nm to approximately 560 nm.

The third color may be blue corresponding to a wavelength region of approximately 420 nm to approximately 460 nm.

Hereinafter, an embodiment will be described for a case that the first color, the second color, and the third color are red, green, and blue, respectively, but this is only an example, and colors corresponding to the emission areas EA and their respective wavelength regions are not limited to the above example.

According to a first embodiment, each of the first light emitting member 131Y, the second light emitting member 132Y, and the third light emitting member 133 may include a light emitting device LE emitting light of a wavelength region lower than a wavelength region of the third color.

For example, each of the first light emitting member 131Y, the second light emitting member 132Y, and the third light emitting member 133 may include a light emitting device LE emitting light of an ultraviolet wavelength region. In an embodiment, each of the first light emitting member 131Y, the second light emitting member 132Y, and the third light emitting member 133 may include a light emitting device LE emitting ultraviolet light corresponding to a wavelength region of approximately 400 nm to approximately 420 nm.

In another embodiment, as described below, according to embodiments, at least one of the first light emitting member 131Y, the second light emitting member 132Y, and the third light emitting member 133 may include a light emitting device LE emitting blue light corresponding to a wavelength region of approximately 440 nm to approximately 470 nm.

Referring to FIG. 7, a vertical-type light emitting device LE may include a first semiconductor layer SEL1 and a second semiconductor layer SEL2 facing each other and doped with dopants of different conductivity types and an active layer MQW interposed between the first semiconductor layer SEL1 and the second semiconductor layer SEL2.

The vertical-type light emitting device LE may further include a first electrode (diode electrode) DE1 disposed below the first semiconductor layer SEL1 and a second electrode DE2 disposed on the second semiconductor layer SEL2. According to packaging of the vertical-type light emitting device LE, the first electrode DE1 and the second electrode DE2 may be omitted.

The first semiconductor layer SEL1 may include a GaN semiconductor doped with a p-type dopant. In an embodiment, the first semiconductor layer SEL1 may include a p-type dopant such as Mg, Zn, Ca, Se, and Ba.

The light emitting device LE may further include an electron blocking layer (not illustrated) disposed between the first semiconductor layer SEL1 and the active layer MQW. The electron blocking layer may include AlGaN doped with a p-type dopant. The electron blocking layer may prevent movement of electrons from the active layer MQW to the first semiconductor layer SEL1.

The active layer MQW may emit energy in the form of photons while generating electron-hole pairs by combining holes and electrons each supplied from the first semiconductor layer SEL1 and the second semiconductor layer SEL2 in response to the driving current.

According to the first embodiment, the active layer MQW of the light emitting device LE may emit light corresponding to a wavelength region of about 400 nm to about 420 nm.

In another embodiment, in embodiments to be described later, the active layer MQW of the light emitting device LE may emit light corresponding to a wavelength region of about 440 nm to about 470 nm.

The active layer MQW may include a material having a single or multi-quantum well structure.

In an embodiment, the active layer MQW may have a multiple quantum well structure in which well layers and barrier layers are alternately stacked each other. The well layer may include InGaN. The barrier layer may include GaN or AlGaN. The well layer may have a thickness of approximately 1 nm to approximately 4 nm, and the barrier layer may have a thickness of approximately 3 nm to approximately 10 nm. However, this is only an example, and the material and the structure of the active layer MQW of the light emitting device LE may be variously modified.

For example, in another embodiment, the active layer MQW may have a structure in which semiconductor materials having large band gap energy and semiconductor materials having small band gap energy are alternately stacked each other.

In another embodiment, the active layer MQW may include Group III to Group V semiconductor materials corresponding to a target wavelength region of the light emitting device LE.

The light emitting device LE may further include a superlattice layer (not illustrated) disposed between the active layer MQW and the second semiconductor layer SEL2 and reducing a stress difference between the active layer MQW and the second semiconductor layer SEL2. The superlattice layer may include InGaN or GaN.

The second semiconductor layer SEL2 may include an GaN semiconductor doped with an n-type dopant. In an embodiment, the second semiconductor layer SEL2 may include an n-type dopant such as Si, Ge, or Sn.

As illustrated in FIG. 6, according to the first embodiment, each of the first light emitting member 131Y, the second light emitting member 132Y, and the third light emitting member 133 may include the light emitting device LE emitting the ultraviolet light, and thus may include the second color conversion layer CC2 including the quantum dots QD1, QD2, and QD3 for converting the ultraviolet light of the light emitting device LE into respective colors and the first color conversion layer CC1 for protecting the quantum dots QD1, QD2, and QD3 of the second color conversion layer CC2 from heat generated by the light emitting device LE.

For example, each of the first light emitting member 131Y, the second light emitting member 132Y, and the third light emitting member 133 may include the light emitting device LE emitting the ultraviolet light of which a wavelength region is lower than that of the blue, the first color conversion layer CC1 absorbing a portion of the light of the light emitting device LE, the light scattering layer LSC scattering another portion of the light of the light emitting device LE, and the second color conversion layer CC2 including the quantum dots QD1, QD2, and QD3 corresponding to the respective colors.

The first color conversion layer CC1 of each of the first light emitting member 131Y corresponding to red and the second light emitting member 132Y corresponding to green may include phosphors (phosphors of yellow PY) corresponding to yellow of which a wavelength region is between the red and the green. For example, the first color conversion layer CC1 of each of the first light emitting member 131Y and the second light emitting member 132Y may include a base resin and the phosphors of yellow PY dispersed in the base resin.

In an embodiment, (Y, Gd)₃Al₅O₁₂:Ce³⁺ or (La, Y)₃Si₆N₁₁:Ce³⁺ may be selected as the phosphor of yellow PY.

The first color conversion layer CC1 may be to protect the quantum dots of the second color conversion layer CC2 from photons of the light emitting device LE, and an interval between wavelength regions of red and green and wavelength region of ultraviolet may be relatively large. Therefore, it may be expected that an effect of the first color conversion layer CC1 on red light emission efficiency of the first light emitting member 131Y and green light emission efficiency of the second light emitting member 132Y will be relatively small.

Accordingly, according to the first embodiment, the first color conversion layers CC1 of the first light emitting member 131Y and the second light emitting member 132Y may include the same phosphors of yellow PY, which may be advantageous in simplifying structures of the first color conversion layers CC1.

However, since the wavelength region of the blue is relatively adjacent to the ultraviolet wavelength region, there is a possibility that blue light emission efficiency of the third light emitting member 133 may be lowered by the first color conversion layer CC1. Accordingly, the first color conversion layer CC1 of the third light emitting member 133 may include phosphors (phosphors of blue PB) corresponding to the blue.

For example, the first color conversion layer CC1 of the third light emitting member 133 may include a base resin and the phosphors of blue PB dispersed in the base resin.

In an embodiment, BaAlMg₁₀O₁₇:Eu²⁺ may be selected as the phosphor of blue PB.

The base resin of the first color conversion layer CC1 may include an organic material cured by ultraviolet rays or heat and having light-transmitting properties. In an embodiment, the base resin of the first color conversion layer CC1 may include an epoxy-based resin, an acrylic resin, a cardo-based resin, an imide-based resin, or the like.

The first color conversion layer CC1 may further include scatterers for inducing light absorption of the phosphors.

The light scattering layer LSC may scatter the light converted by the first color conversion layer CC1 or another portion of the light of the light emitting device LE that is not absorbed by the first color conversion layer CC1 and is not transmitted through the light scattering layer LSC.

The light scattering layer LSC may include a material including a base resin and scatterers dispersed in the base resin.

The base resin of the light scattering layer LSC may include an organic material cured by ultraviolet rays or heat and having light-transmitting properties. In an embodiment, the base resin of the light scattering layer LSC may include an epoxy-based resin, an acrylic resin, a cardo-based resin, an imide-based resin, or the like.

The scatterer of the light scattering layer LSC may include a material having a reflectivity of about 95% or more and may have an approximately spherical shape. A size of the scatterer may be in the range of about 10 nm to about 500 nm.

In an embodiment, the scatterer may include at least one of metal oxides such as titanium oxide (TiO₂), silicon oxide (SiO₂), aluminum oxide (Al₂O₃), and zirconium oxide (ZrO₂).

The second color conversion layer CC2 of the first light emitting member 131Y may include first quantum dots QD1 corresponding to red. For example, the second color conversion layer CC2 of the first light emitting member 131Y may include a base resin and the first quantum dots QD1 dispersed in the base resin.

The second color conversion layer CC2 of the second light emitting member 132Y may include second quantum dots QD2 corresponding to green. For example, the second color conversion layer CC2 of the second light emitting member 132Y may include a base resin and the second quantum dots QD2 dispersed in the base resin.

The second color conversion layer CC2 of the third light emitting member 133 may include third quantum dots QD3 corresponding to blue. For example, the second color conversion layer CC2 of the third light emitting member 133 may include a base resin and the third quantum dots QD3 dispersed in the base resin.

The second color conversion layer CC2 may further include scatterers.

The base resin of the second color conversion layer CC2 may include an epoxy-based resin, an acrylic resin, a cardo-based resin, an imide-based resin, or the like.

Each of the first quantum dot QD1, the second quantum dot QD2, and the third quantum dot QD3 may include group IV nanocrystals, group II-VI compound nanocrystals, group III-V compound nanocrystals, group IV-VI compound nanocrystals, or combinations thereof.

Each of the first quantum dot QD1, the second quantum dot QD2, and the third quantum dot QD3 may have a structure that includes a core and a shell overcoating the core.

In an embodiment, the core of each of the first quantum dot QD1, the second quantum dot QD2, and the third quantum dot QD3 may include at least one of CdS, CdSe, CdTe, ZnS, ZnSe, ZnTe, GaN, GaP, GaAs, GaSb, AlN, AlP, AlAs, AlSb, InP, InAs, InSb, SiC, Ca, Se, In, P, Fe, Pt, Ni, Co, Al, Ag, Au, Cu, FePt, Fe₂O₃, Fe₃O₄, Si, and Ge.

The shell of each of the first quantum dot QD1, the second quantum dot QD2, and the third quantum dot QD3 may include at least one of ZnS, ZnSe, ZnTe, CdS, CdSe, CdTe, HgS, HgSe, HgTe, AlN, AlP, AlAs, AlSb, GaN, GaP, GaAs, GaSb, GaSe, InN, InP, InAs, InSb, TlN, TlP, TlAs, TlSb, PbS, Pb Se, and PbTe.

According to the first embodiment, each of the first quantum dot QD1, the second quantum dot QD2, and the third quantum dot QD3 may include a composition of InP or InZnP. In another embodiment, each of the first quantum dot QD1, the second quantum dot QD2, and the third quantum dot QD3 may have perovskite, and may include any one composition of CsPbCl₃, CsPbBr₃, and CsPbI₃.

The first quantum dot QD1 may correspond to a color (e.g., red) of a wavelength region higher than those of the second color (e.g., green) and the third color (e.g., blue), and may thus have a diameter greater than those of the second quantum dot QD2 and the third quantum dot QD3.

The second quantum dot QD2 may correspond to a color of a wavelength region higher than that of the third color, and may thus have a diameter greater than that of the third quantum dot QD3.

In an embodiment, in case that the first color, the second color, and the third color are in a wavelength region of about 630 nm, a wavelength region of about 530 nm, and a wavelength region of about 450 nm, respectively, diameters of the first quantum dot QD1, the second quantum dot QD2, and the third quantum dot QD3 may be about 3.0 nm, about 1.5 nm, and about 1 nm, respectively. This is only an example, and the diameter of each of the first quantum dot QD1, the second quantum dot QD2, and the third quantum dot QD3 may be freely selected according to a material of each of the first quantum dot QD1, the second quantum dot QD2, and the third quantum dot QD3 and a wavelength region of the light of the light emitting device LE.

For example, the first light emitting member 131Y corresponding to the first emission area EA1 emitting the light of the first color may include a light emitting device LE emitting light of a wavelength region lower than that of the third color, a first color conversion layer CC1 covering the light emitting device LE and including phosphors PY corresponding to a wavelength region between the first color and the second color, a light scattering layer LSC disposed on the first color conversion layer CC1, and a second color conversion layer CC2 disposed on the light scattering layer LSC and including first quantum dots QD1 corresponding to a wavelength region of the first color.

The first color conversion layer CC1 of the first light emitting member 131Y may include the phosphors PY corresponding to the wavelength region between the first color and the second color, and thus, may absorb a portion of the light of the light emitting device LE and may convert the absorbed light into the wavelength region between the first color and the second color.

The light scattering layer LSC of the first light emitting member 131Y may include scatterers, and thus may scatter the light emitted from the first color conversion layer CC1 of the first light emitting member 131Y or another portion of the light of the light emitting device LE that is not absorbed by the first color conversion layer CC1 and is not transmitted through the light scattering layer LSC.

The second color conversion layer CC2 of the first light emitting member 131Y may include the first quantum dots QD1, and thus may convert the light scattered by the light scattering layer LSC or still another portion of the light of the light emitting device LE that is not absorbed by the first color conversion layer CC1 and is transmitted through the light scattering layer LSC into the wavelength region of the first color.

Accordingly, the first light emitting member 131Y may emit light of the first color by the second color conversion layer CC2.

The second light emitting member 132Y corresponding to the second emission area EA2 emitting the light of the second color may include a light emitting device LE emitting light of a wavelength region lower than that of the third color, a first color conversion layer CC1 covering the light emitting device LE and including phosphors PY corresponding to a wavelength region between the first color and the second color, a light scattering layer LSC disposed on the first color conversion layer CC1, and a second color conversion layer CC2 disposed on the light scattering layer LSC and including second quantum dots QD2 corresponding to a wavelength region of the second color.

The first color conversion layer CC1 of the second light emitting member 132Y may include the phosphors PY corresponding to the wavelength region between the first color and the second color, and thus, may absorb a portion of the light of the light emitting device LE and may convert the absorbed light into the wavelength region between the first color and the second color.

The light scattering layer LSC of the second light emitting member 132Y may include scatterers, and thus may scatter the light emitted from the first color conversion layer CC1 of the second light emitting member 132Y or another portion of the light of the light emitting device LE that is not absorbed by the first color conversion layer CC1 and is not transmitted through the light scattering layer LSC.

The second color conversion layer CC2 of the second light emitting member 132Y may include the second quantum dots QD2, and thus may convert the light scattered by the light scattering layer LSC or still another portion of the light of the light emitting device LE that is not absorbed by the first color conversion layer CC1 and is transmitted through the light scattering layer LSC into the wavelength region of the second color.

Accordingly, the second light emitting member 132Y may emit light of the second color by the second color conversion layer CC2.

The third light emitting member 133 corresponding to the third emission area EA3 emitting the light of the third color may include a light emitting device LE emitting light of a wavelength region lower than that of the third color, a first color conversion layer CC1 covering the light emitting device LE and including phosphors PB corresponding to a wavelength region of the third color, a light scattering layer LSC disposed on the first color conversion layer CC1, and a second color conversion layer CC2 disposed on the light scattering layer LSC and including third quantum dots QD3 corresponding to the wavelength region of the third color.

The first color conversion layer CC1 of the third light emitting member 133 may include the phosphors PB corresponding to the wavelength region of the third color, and thus, may absorb a portion of the light of the light emitting device LE and may convert the absorbed light into the wavelength region of the third color.

The light scattering layer LSC of the third light emitting member 133 may include scatterers, and thus may scatter the light emitted from the first color conversion layer CC1 of the third light emitting member 133 or another portion of the light of the light emitting device LE that is not absorbed by the first color conversion layer CC1 and is not transmitted through the light scattering layer LSC.

The second color conversion layer CC2 of the third light emitting member 133 may include the third quantum dots QD3, and thus may convert the light scattered by the light scattering layer LSC or still another portion of the light of the light emitting device LE that is not absorbed by the first color conversion layer CC1 and is transmitted through the light scattering layer LSC into the wavelength region of the third color.

Accordingly, the third light emitting member 133 may emit light of the third color by the second color conversion layer CC2.

The bank 140 may correspond to a boundary between the emission areas EA.

The bank 140 may be disposed to be spaced apart from the light emitting device LE and to surround the light emitting device LE.

The bank 140 may include a light-absorbing material such as a black matrix.

The display panel 100A according to the first embodiment may further include a transistor array 120 disposed on the substrate 110. The light emitting members 130 and the bank 140 may be disposed on the transistor array 120.

The transistor array 120 may include at least one thin film transistors T1 disposed on the substrate 110 and corresponding to each of the emission areas EA, a common line CL disposed on the substrate 110 and extending in a direction corresponding to arrangement directions DR1 and DR2 of the emission areas EA, a planarization layer 121 covering the at least one thin film transistors T1 and the common line CL of each of the emission areas EA, multiple pixel electrodes PE disposed on the planarization layer 121, each corresponding to the emission areas EA, and multiple common electrodes CE disposed on the planarization layer 121, each corresponding to the emission areas EA, spaced apart from the pixel electrodes PE, and electrically connected to the common line CL.

Each of the at least one thin film transistors T1 corresponding to each of the emission areas EA may include an active layer (not illustrated) disposed on the substrate 110 and made of a semiconductor material and a gate electrode overlapping a channel region of the active layer. The active layer and the gate electrode may be insulated from each other by a gate insulating film disposed therebetween.

The active layer may include a source region and a drain region contacting each respective side of the channel region. Any one of the source region and the drain region may be electrically connected to the pixel electrode PE on the planarization layer 121 through a first contact hole CH1 penetrating through the planarization layer 121. The other of the source region and the drain region may be electrically connected to the power supply line PL (see FIG. 5).

Each of the at least one thin film transistors T1 corresponding to each of the emission areas EA may further include a source electrode and a drain electrode disposed at a layer different from the gate electrode and each respectively electrically connected to the source region and the drain region contacting each respective side of the channel region of the active layer. The pixel electrode PE for this embodiment may be electrically connected to any one of the source electrode and the drain electrode rather than the active layer.

The common line CL may be insulated from the thin film transistor T1, and may extend in at least one of the first direction DR1 and the second direction DR2.

The common line CL may be electrically connected to the common electrode CE on the planarization layer 121 through a second contact hole CH2 penetrating through the planarization layer 121.

The planarization layer 121 may include at least one organic insulating materials such as an acrylic resin, an epoxy resin, a phenolic resin, a polyamide resin, and a polyimide resin.

A portion of the emission areas EA may correspond to the pixel electrode PE, and another portion of the emission areas EA may correspond to the common electrode CE.

The pixel electrode PE and the common electrode CE may be formed as a single layer or multiple layers including any one of molybdenum (Mo), aluminum (Al), chromium (Cr), gold (Au), titanium (T1), nickel (Ni), neodymium (Nd), copper (Cu), and alloys thereof.

In the light emitting device LE of each of the light emitting members 130, the first electrode DE1 (see FIG. 7) may be disposed on the pixel electrode PE, may face the pixel electrode PE, and may be electrically connected to the pixel electrode PE. For example, the first electrode DE1 (see FIG. 7) may be electrically connected to the pixel electrode PE through contact with the pixel electrode PE.

In case that the light emitting device LE of each of the light emitting members 130 is a vertical-type light emitting device, the second electrode DE2 (see FIG. 7) of the light emitting device LE may face the first electrode DE1, and may be electrically connected to the common electrode CE through a bonding wire BW.

In another embodiment, although not illustrated separately, in case that the light emitting device LE of each of the light emitting members 130 is a lateral-type light emitting device, the first electrode DE1 and the second electrode DE2 of the light emitting device LE may be electrically connected to the pixel electrode PE and the common electrode CE, respectively, through respective bonding wires BW.

The display panel 100A according to the first embodiment may further include a protective layer 150 disposed on the light emitting members 130 and the bank 140, and a color filter layer 160 disposed on the protective layer 150.

The protective layer 150 may include an insulating material having light-transmitting properties and hydrophobicity. In an embodiment, the protective layer 150 may include SiO₂₋ₓ or SiO₂. x may be 0, 1, or 2.

Since the second color conversion layer CC2 may be sealed by the protective layer 150, the quantum dots QD1, QD2, and QD3 of the second color conversion layer CC2 may be protected from moisture. Accordingly, rapid deterioration of the quantum dots QD1, QD2, and QD3 due to penetration of the moisture may be prevented.

The color filter layer 160 may include first color filters 161 corresponding to the first light emitting members 131Y emitting the light of the first color, second color filters 162 corresponding to the second light emitting members 132Y emitting the light of the second color, third color filters 163 corresponding to the third light emitting members 133 emitting the light of the third color, and a light blocking member 164 corresponding to the bank 140.

The light blocking member 164 may include a light-absorbing material such as a black matrix.

The first color filter 161 may include a dye or a pigment of the first color, and may selectively transmit light of a wavelength region corresponding to the first color. The first color filter 161 may absorb or block the light of the second color conversion layer CC2 except for the light of the wavelength region corresponding to the first color.

The second color filter 162 may include a dye or a pigment of the second color, and may selectively transmit light of a wavelength region corresponding to the second color. The second color filter 162 may absorb or block the light of the second color conversion layer CC2 except for the light of the wavelength region corresponding to the second color.

The third color filter 163 may include a dye or a pigment of the third color, and may selectively transmit light of a wavelength region corresponding to the third color. The third color filter 163 may absorb or block the light of the second color conversion layer CC2 except for the light of the wavelength region corresponding to the third color.

Color mixing of the light emitted from each of the first light emitting member 131Y, the second light emitting member 132Y, and the third light emitting member 133 neighboring to each other and corresponding to different colors may be prevented by the bank 140.

As described above, according to the first embodiment, the first color conversion layers CC1 may be disposed between the second color conversion layers CC2 including the quantum dots QD1, QD2, and QD3 and the light emitting devices LE, and thus, the second color conversion layers CC2 may be spaced apart from the light emitting devices LE.

The first color conversion layers CC1 may include not only base resins, but also phosphors PY or PB absorbing a portion of the light from the light emitting devices LE. Accordingly, an amount of photons of the light emitting devices LE may be decreased by the phosphors PY or PB of the first color conversion layers CC1.

Therefore, a degree to which the quantum dots QD1, QD2, and QD3 of the second color conversion layers CC2 are directly exposed to photons emitted from the light emitting devices LE may be reduced. For example, the quantum dots QD1, QD2, and QD3 of the second color conversion layers CC2 may be relatively less exposed to heat generated by the light emitting devices LE.

Accordingly, damage to the quantum dots QD1, QD2, and QD3 of the second color conversion layers CC2 due to the heat generated by the light emitting devices LE may be delayed. Therefore, color purity of the display panel 100A from the second color conversion layers CC2 including the quantum dots QD1, QD2, and QD3 may be improved, and a lifespan of the display panel 100A may be extended by the first color conversion layers CC1. Accordingly, quality reliability of the display panel 100A may be improved.

Since the first color conversion layers CC1 include phosphors PY or PB, a significant decrease in light efficiency by the first color conversion layers CC1 may be also prevented.

A light wavelength conversion efficiency by the second color conversion layers CC2 may be also improved by the light scattering layers LSC disposed below the second color conversion layers CC2.

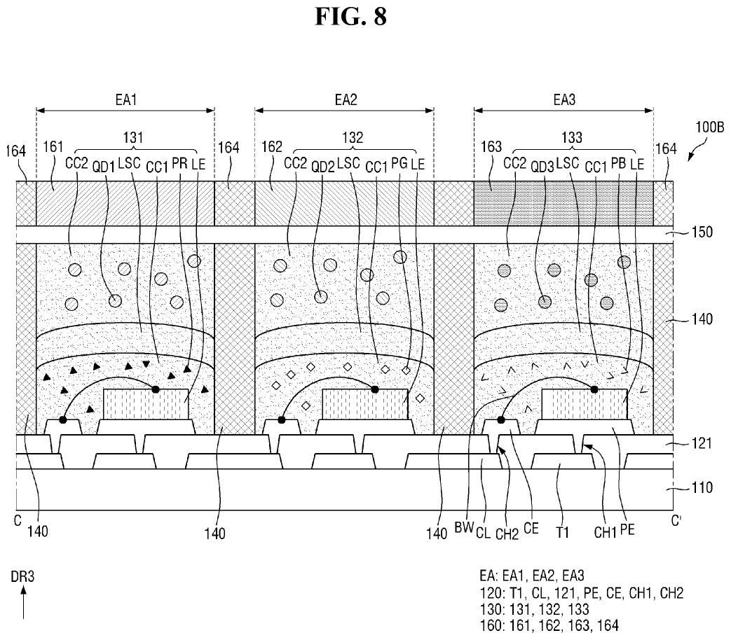

FIG. 8 is a schematic cross-sectional view taken along line C-C′ of FIG. 4 according to a second embodiment.

Referring to FIG. 8, a display panel 100B according to a second embodiment may be the same as the display panel 100A according to the first embodiment except that a first color conversion layer CC1 of a first light emitting member 131 may include phosphors (phosphors of red PR) corresponding to red rather than the phosphors of yellow PY and a first color conversion layer CC1 of a second light emitting member 132 may include phosphors (phosphors of green PG) corresponding to green rather than the phosphors of yellow PY, and an overlapping description will be omitted below.

According to the second embodiment, the first color conversion layer CC1 of the first light emitting member 131 may include phosphors of red PR corresponding to the first emission area EA1. For example, the first color conversion layer CC1 of the first light emitting member 131 may include a base resin and the phosphors of red PR dispersed in the base resin.

The phosphor of red PR may include a material converting ultraviolet light of the light emitting device LE into a wavelength region of the red.

For example, the phosphor of red PR may include a material converting ultraviolet light into a wavelength region of approximately 660 nm and having a full width at half maximum of about 20 nm or less. Mg₄GeO₃F:Mn⁴⁺ or 3.5MgO·0.5MgF₂·GeO₂:Mn⁴⁺ may be selected as the phosphor of red PR.

In another embodiment, the phosphor of red PR may include a material converting ultraviolet light into a wavelength region of approximately 632 nm and having a full width at half maximum of about 10 nm or less. K₂(Si, Ge, Ti)SiF₆:Mn⁴⁺ may be selected as the phosphor of red PR.

In another embodiment, the phosphor of red PR may include a material converting ultraviolet light into a wavelength region of approximately 610 nm to approximately 670 nm and having a full width at half maximum of approximately 90 nm or less. (Sr, Ca)AlSiN₃:Eu²⁺ may be selected as the phosphor of red PR.

The first color conversion layer CC1 of the second light emitting member 132 may include the phosphors of green PG corresponding to the second emission area EA2. For example, the first color conversion layer CC1 of the second light emitting member 132 may include a base resin and the phosphors of green PG dispersed in the base resin.

The phosphor of green PG may include a material converting ultraviolet light of the light emitting device LE into a wavelength region of the green.

For example, at least one of Beta-SiAlON:Eu²⁺, SrGa₂S₄:Eu²⁺, BaAlMg₁₀O₁₇:Eu²⁺, Mn²⁺, (Sr, Ba, Mg)₂SiO₄:Eu²⁺, and (Lu,Y)₃(Al, Ga)₅O₁₂:Ce³⁺ may be selected as the phosphor of green PG.

As described above, according to the second embodiment, the first color conversion layer CC1 of the first light emitting member 131 may include the phosphors of red PR, and the first color conversion layer CC1 of the second light emitting member 132 may include the phosphors of green PG. Accordingly, a decrease in color purity due to the first color conversion layer CC1 may be improved.

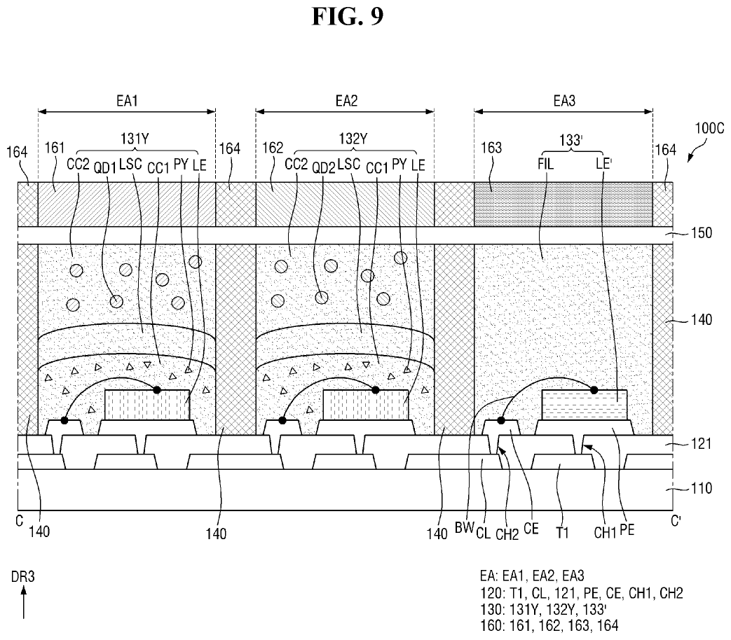

FIG. 9 is a schematic cross-sectional view taken along line C-C′ of FIG. 4 according to a third embodiment.

Referring to FIG. 9, a display panel 100C according to a third embodiment is the same as the display panel 100A according to the first embodiment except that a third light emitting member 133′ corresponding to the third emission area EA3 of the third color may include a light emitting device LE′ emitting light of a third color and a filling layer FIL covering the light emitting device LE′ unlike the first light emitting member 131Y and the second light emitting member 132Y, and an overlapping description will be omitted below.

According to the third embodiment, as in the first embodiment, each of the first light emitting member 131Y and the second light emitting member 132Y may include a light emitting device LE emitting ultraviolet light, a first color conversion layer CC1 covering the light emitting device LE and including phosphors of yellow PY, a light scattering layer LSC disposed on the first color conversion layer CC1, and a second color conversion layer CC2 covering the light scattering layer LSC and including quantum dots QD1 and QD2 corresponding to respective colors.

Unlike the red of the first emission area EA1 and the green of the second emission area EA2, the blue of the third emission area EA3 may be a wavelength region adjacent to the ultraviolet light, and thus, wavelength conversion efficiency may be relatively low.

Accordingly, according to the third embodiment, the third light emitting member 133′ corresponding to the third emission area EA3 may include the light emitting device LE′ emitting blue light rather than ultraviolet light, and may emit blue light of the light emitting device LE′ without converting a wavelength of the blue light.

The third light emitting member 133′ may further include a filling layer FIL protecting the light emitting device LE′ and transmitting the blue light from the light emitting device LE′.

The filling layer FIL may include a base resin such as an epoxy-based resin, an acrylic resin, a cardo-based resin, and an imide-based resin.

In another embodiment, the filling layer FIL may further include scatterers.

Similar to the scatterer of the light scattering layer LSC, the scatterer of the filling layer FIL may include a material having a reflectivity of about 95% or more and may have an approximately spherical shape. A size of the scatterer may be in a range of about 10 nm to about 500 nm.

In an embodiment, the scatterer of the filling layer FIL may include at least one metal oxides such as titanium oxide (TiO₂), silicon oxide (SiO₂), aluminum oxide (Al₂O₃), and zirconium oxide (ZrO₂).

As described above, according to the third embodiment, the third light emitting member 133′ corresponding to the third emission area EA3 of the blue may include the light emitting device LE′ emitting blue light, and thus, light loss in a process of converting the ultraviolet light into the blue light may be reduced. Accordingly, emission efficiency and luminance of the blue light in the third emission area EA3 may be improved.

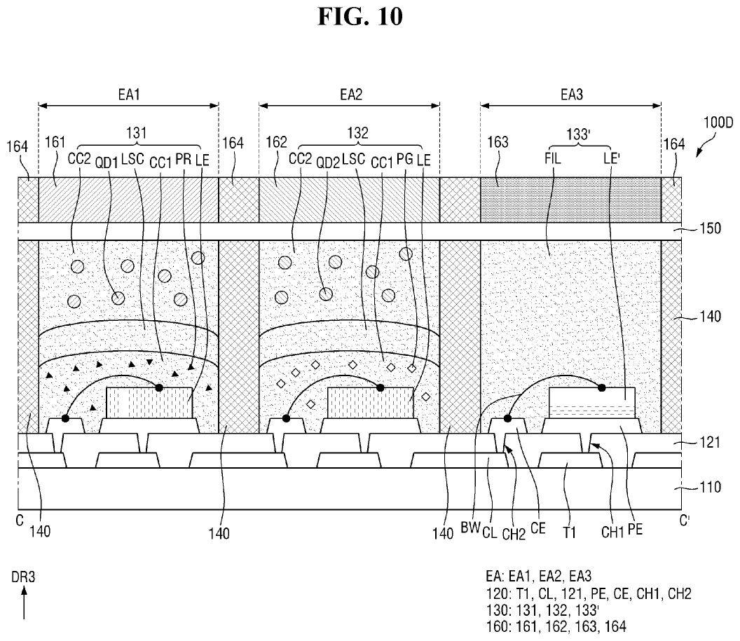

FIG. 10 is a schematic cross-sectional view taken along line C-C′ of FIG. 4 according to a fourth embodiment.

Referring to FIG. 10, a display panel 100D according to a fourth embodiment is the same as the display panel 100C according to the third embodiment except that a first color conversion layer CC1 of a first light emitting member 131 may include phosphors (phosphors of red PR) corresponding to red rather than the phosphors of yellow PY and a first color conversion layer CC1 of a second light emitting member 132 may include phosphors (phosphors of green PG) corresponding to green rather than the phosphors of yellow PY, and an overlapping description will be omitted below.

The first color conversion layer CC1 of the first light emitting member 131 and the first color conversion layer CC1 of the second light emitting member 132 according to the fourth embodiment are the same as those of the display panel 100B according to the second embodiment, and an overlapping description will be omitted below.

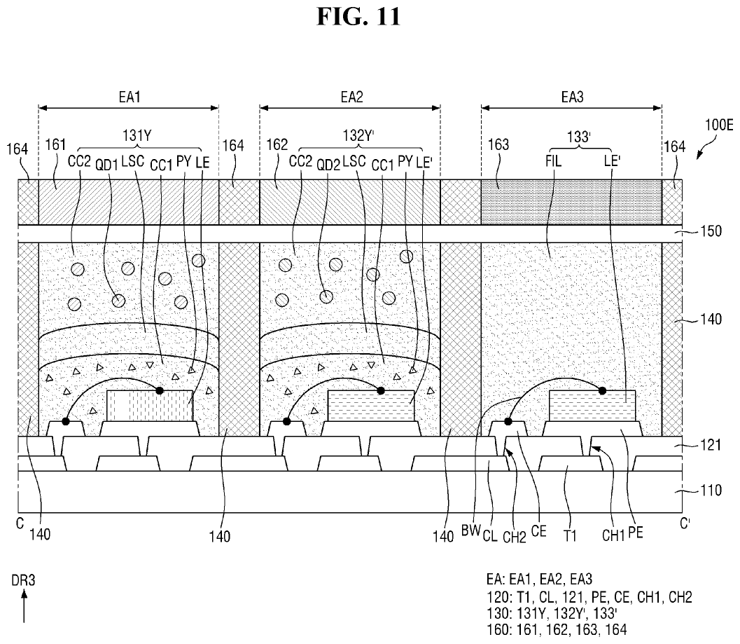

FIG. 11 is a schematic cross-sectional view taken along line C-C′ of FIG. 4 according to a fifth embodiment.

Referring to FIG. 11, a display panel 100E according to a fifth embodiment is the same as the display panel 100C according to the third embodiment except that a second light emitting member 132Y′ corresponding to the second emission area EA2 emitting the green light may include a light emitting device LE′ emitting light of a third color, and an overlapping description will be omitted below.

Since the green light is a wavelength region more adjacent to the blue light than the ultraviolet light, even though the blue light of the light emitting device LE′ is slightly mixed with the green light of the second light emitting member 132Y′, a deterioration degree of color purity of the green light may be low.

Accordingly, in case that the blue light of the light emitting device LE′ is converted into the green light, considering light loss due to the conversion of the ultraviolet light to the green light, color purity of the green light may be slightly lowered, but emission efficiency and luminance of the green light in the emission area EA2 may be improved.

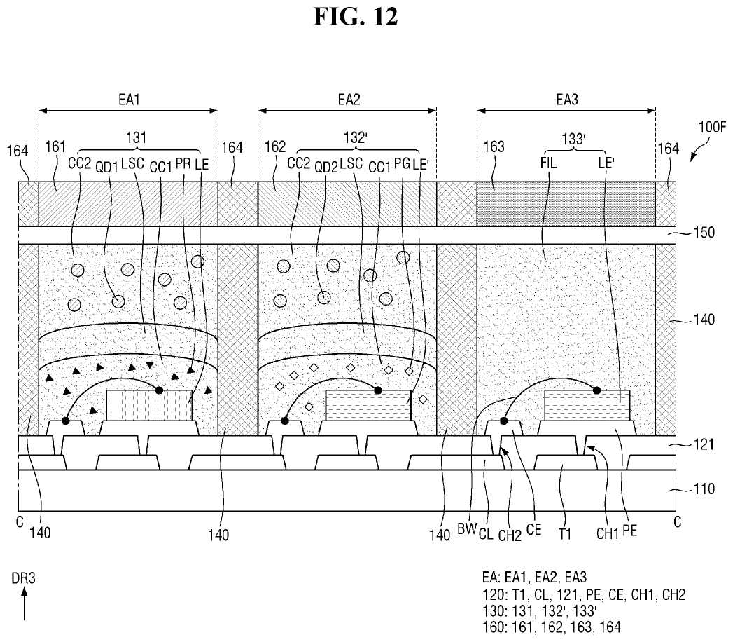

FIG. 12 is a schematic cross-sectional view taken along line C-C′ of FIG. 4 according to a sixth embodiment.

Referring to FIG. 12, a display panel 100F according to a sixth embodiment is the same as the display panel 100E according to the fifth embodiment except that a first color conversion layer CC1 of a first light emitting member 131 may include phosphors (phosphors of red PR) corresponding to red rather than the phosphors of yellow PY and a first color conversion layer CC1 of a second light emitting member 132′ may include phosphors (phosphors of green PG) corresponding to green rather than the phosphors of yellow PY, and an overlapping description will be omitted below.

The first color conversion layer CC1 of the second light emitting member 132′ may include phosphors of green PG converting blue light of a light emitting device LE′ into green light.

In an embodiment, at least one of Beta-SiAlON:Eu²⁺, SrGa₂S₄:Eu²⁺, BaAlMg₁₀O₁₇:Eu²⁺, Mn²⁺, (Sr, Ba, Mg)₂SiO₄:Eu²⁺, and (Lu,Y)₃(Al, Ga)₅O₁₂:Ce³⁺ may be selected as the phosphor of green PG.

Beta-SiAlON:Eu²⁺ may be selected as the phosphor of green PG according to the sixth embodiment.

The first color conversion layer CC1 of the first light emitting member 131 according to the sixth embodiment is the same as that of the display panel 100B according to the second embodiment, and an overlapping description will be omitted below.

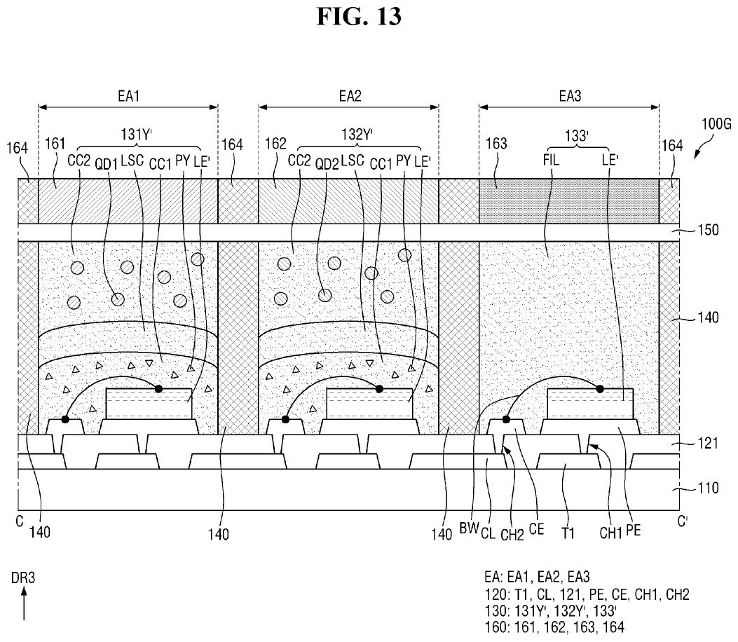

FIG. 13 is a schematic cross-sectional view taken along line C-C′ of FIG. 4 according to a seventh embodiment.

Referring to FIG. 13, a display panel 100G according to a seventh embodiment is the same as the display panel 100C according to the third embodiment except that each of a first light emitting member 131Y′ corresponding to the first emission area EA1 emitting the red light and a second light emitting member 132Y′ corresponding to the second emission area EA2 emitting the green light may include a light emitting device LE′ emitting light of a third color, and an overlapping description will thus be omitted below.

Unlike third, fourth, fifth and sixth embodiments, the first light emitting member 131Y′, the second light emitting member 132Y′, and the third light emitting member 133 may include light emitting devices LE′ emitting blue light in the same way, and thus, a process of preparing and mounting the light emitting devices LE′ may be simplified.

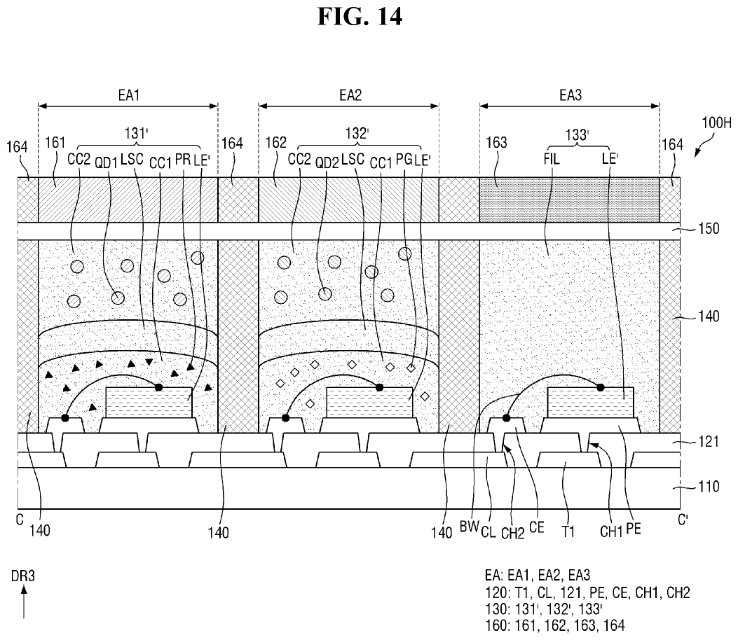

FIG. 14 is a schematic cross-sectional view taken along line C-C′ of FIG. 4 according to an eighth embodiment.

Referring to FIG. 14, a display panel 100H according to an eighth embodiment is the same as the display panel 100F according to the seventh embodiment except that a first color conversion layer CC1 of a first light emitting member 131 may include phosphors (phosphors of red PR) corresponding to red rather than the phosphors of yellow PY and a first color conversion layer CC1 of a second light emitting member 132 may include phosphors (phosphors of green PG) corresponding to green rather than the phosphors of yellow PY, and an overlapping description will be omitted below.

The first color conversion layer CC1 of the second light emitting member 131′ may include phosphors of red PR converting blue light of a light emitting device LE′ into red light.

In an embodiment, (Sr, Ca)AlSiN₃:Eu²⁺ or K₂(Si, Ge, T1)F₆:Mn⁴⁺ may be used for the phosphor of red PR according to the eighth embodiment.

The first color conversion layer CC1 of the second light emitting member 132′ according to the eighth embodiment is the same as that of the display panel 100F according to the sixth embodiment, and an overlapping description will be omitted below.

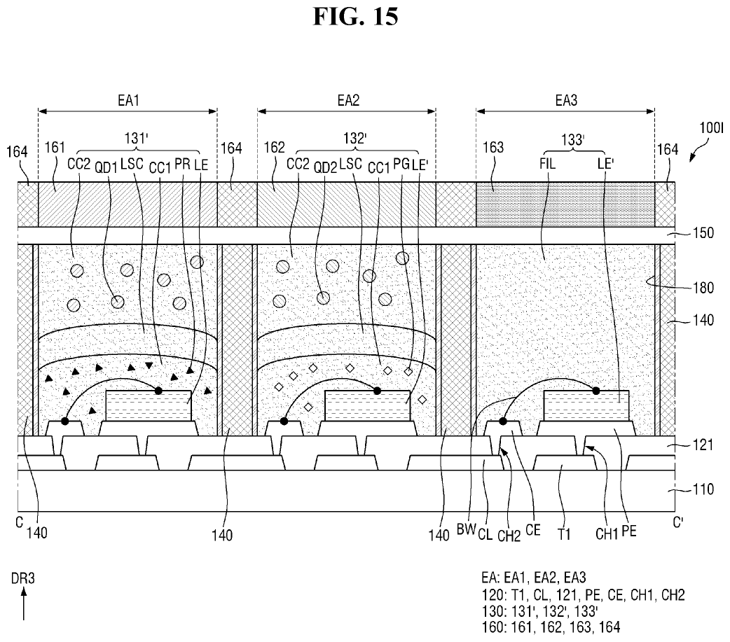

FIG. 15 is a schematic cross-sectional view taken along line C-C′ of FIG. 4 according to a ninth embodiment.

Referring to FIG. 15, a display panel 100I according to a ninth embodiment is the same as each of the display panels according to first to eighth embodiments except that it may further include a reflective layer 180 disposed on an edge of each of the emission areas EA and covering a sidewall of the bank 140, and an overlapping description will be omitted below.

The reflective layer 180 may include a white coating material.

In an embodiment, the reflective layer 180 may include scatterers made of at least one of titanium oxide (TiO₂), silicon oxide (SiO₂), aluminum oxide (Al₂O₃), zirconium oxide (ZrO₂), and boron nitride (BN).

The scatterer of the reflective layer 180 may have a diameter of about 10 nm to about 500 nm and a reflectivity of about 95% or more.

The display panel 100I may further include a reflective layer 180 as described above, and thus, absorption of light of the light emitting devices LE and LE′ by the bank 140 made of a light-absorbing material may be reduced. Accordingly, light efficiency of each of the emission areas EA may be improved.

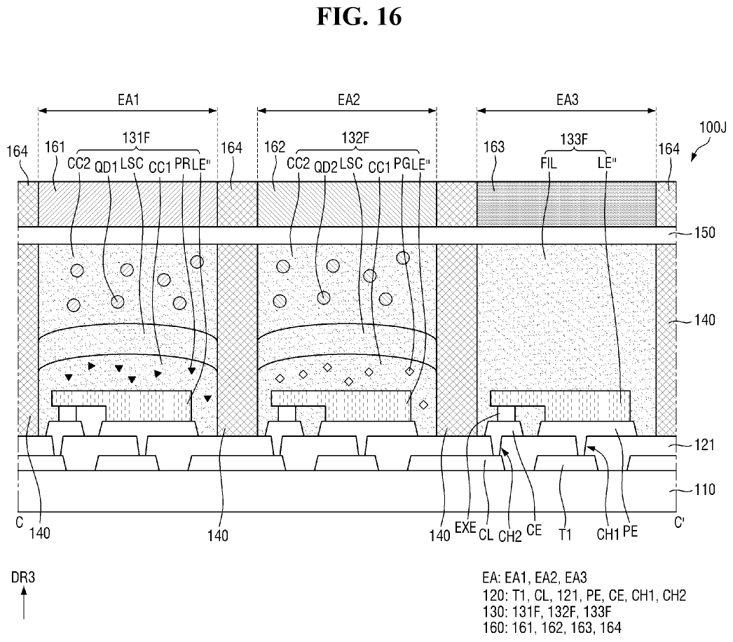

FIG. 16 is a schematic cross-sectional view taken along line C-C′ of FIG. 4 according to a tenth embodiment.

Referring to FIG. 16, a display panel 100J according to a tenth embodiment is the same as each of the display panels according to first to ninth embodiments except that each of a first light emitting member 131F, a second light emitting member 132F, and a third light emitting member 133F may include a flip-type light emitting device LE″ rather than vertical-type light emitting devices LE and LE′, and an overlapping description will be omitted below.

In the flip-type light emitting device LE″, a first electrode and a second electrode may each be electrically connected to the first semiconductor layer SEL1 (see FIG. 7) and the second semiconductor layer SEL2 (see FIG. 7) and may each be disposed parallel to each other. For example, in the flip-type light emitting device LE″, the first electrode and the second electrode may be each disposed parallel to each other on a rear surface opposite to a light emitting surface.

For example, in the flip-type light emitting device LE″, a portion of the rear surface of the light emitting device LE″ may correspond to the first electrode disposed below the first semiconductor layer SEL1, and another portion of the rear surface of the light emitting device LE″ may correspond to the second electrode disposed below the second semiconductor layer SEL2 exposed by removing a portion of the first semiconductor layer SEL1.

The first electrode of the flip-type light emitting device LE″ may be disposed on the pixel electrode PE, may face the pixel electrode PE, and may be electrically connected to the pixel electrode PE. For example, the first electrode DE1 may be electrically connected to the pixel electrode PE through contact with the pixel electrode PE.

The second electrode of the flip-type light emitting device LE″ may be disposed on the common electrode CE and may face the common electrode CE. In an embodiment, the second electrode of the flip-type light emitting device LE″ may be electrically connected to the common electrode CE through an extension electrode EXE. Here, the extension electrode EXE may be disposed between the second electrode and the common electrode CE.

Embodiments have been disclosed herein, and although terms are employed, they are used and are to be interpreted in a generic and descriptive sense only and not for purpose of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the claims.

What is claimed is:

1. A display panel comprising:
a substrate including a plurality of emission areas;
a plurality of light emitting members disposed on the substrate, each of the plurality of light emitting member disposed in the plurality of emission areas; and
a bank disposed on the substrate in a boundary between adjacent ones of the plurality of emission areas, wherein
each of the plurality of light emitting members corresponds to one of two or more different colors, and
one of the plurality of light emitting members includes:
a light emitting device disposed on the substrate and emitting light;
a first color conversion layer disposed on the light emitting device and including phosphors converting a portion of light of the light emitting device into a wavelength region higher than a wavelength region of the light of the light emitting device;
a light scattering layer disposed on the first color conversion layer and scattering another portion of the light of the light emitting device or light of the first color conversion layer; and
a second color conversion layer disposed on the light scattering layer and including quantum dots converting still another portion of the light of the light emitting device or the another portion of the light scattered by the light scattering layer into a wavelength region of the one of two or more different colors which the one of the plurality of the light emitting members corresponds.

2. The display panel of claim 1, wherein
the plurality of light emitting members include:
a first light emitting member emitting light of a first color,
a second light emitting member emitting light of a second color of which a wavelength region is lower than a wavelength region of the first color, and
a third light emitting member emitting light of a third color of which a wavelength region is lower than the wavelength region of the second color.

3. The display panel of claim 2, wherein
each of the first light emitting member, the second light emitting member, and the third light emitting member includes the first color conversion layer, the light scattering layer, and the second color conversion layer,
the light emitting device of each of the plurality of light emitting members emits light of a wavelength region lower than the wavelength region of the third color,
the first color conversion layer of the third light emitting member includes phosphors corresponding to the wavelength region of the third color,
the second color conversion layer of the first light emitting member includes first quantum dots corresponding to the wavelength region of the first color,
the second color conversion layer of the second light emitting member includes second quantum dots corresponding to the wavelength region of the second color, and
the second color conversion layer of the third light emitting member includes third quantum dots corresponding to the wavelength region of the third color.

4. The display panel of claim 3, wherein the phosphors corresponding to the wavelength region of the third color includes BaAlMg₁₀O₁₇:EU²⁺.

5. The display panel of claim 3, wherein the first color conversion layer of the first light emitting member and the first color conversion layer of the second light emitting member each includes phosphors corresponding to a wavelength region between the first color and the second color.

6. The display panel of claim 5, wherein the phosphors corresponding to the wavelength region between the first color and the second color includes (Y, Gd)₃Al₅O₁₂:Ce³⁺ or (La, Y)₃Si₆N₁₁:Ce³⁺.

7. The display panel of claim 3, wherein
the first color conversion layer of the first light emitting member includes first phosphors corresponding to the wavelength region of the first color, and
the first color conversion layer of the second light emitting member includes second phosphors corresponding to the wavelength region of the second color.

8. The display panel according to claim 7, wherein
the first phosphors include (Sr, Ca)AlSiN₃:Eu²⁺, K₂(Si, Ge, T1)F₆:Mn⁴⁺, Mg₄GeO₃F:Mn⁴⁺, or 3.5MgO·0.5MgF₂·GeO₂:Mn⁴⁺, and
the second phosphors include at least one selected from the group of Beta-SiAlON:Eu²⁺, SrGa₂S₄:Eu²⁺, BaAlMg₁₀O₁₇:Eu²⁺, Mn²⁺, (Sr, Ba, Mg)₂SiO₄:Eu²⁺, and (Lu,Y)₃(Al, Ga)₅O₁₂:Ce³⁺.

9. The display panel of claim 2, wherein
the first light emitting member and the second light emitting member each includes the first color conversion layer, the light scattering layer, and the second color conversion layer,
the second color conversion layer of the first light emitting member includes first quantum dots corresponding to the wavelength region of the first color,
the second color conversion layer of the second light emitting member includes second quantum dots corresponding to the wavelength region of the second color,
the light emitting device of the third light emitting member emits light of the wavelength region of the third color, and
the third light emitting member includes a filling layer disposed on the light emitting device.

10. The display panel of claim 9, wherein the filling layer of the third light emitting member includes scatterers scattering the light of the light emitting device.

11. The display panel of claim 9, wherein the first color conversion layer of the first light emitting member and the first color conversion layer of the second light emitting member each includes phosphors corresponding to a wavelength region between the first color and the second color.

12. The display panel of claim 11, wherein the phosphors corresponding to the wavelength region between the first color and the second color includes (Y, Gd)₃Al₅O₁₂:Ce³⁺ or (La, Y)₃Si₆N₁₁:Ce³⁺.

13. The display panel of claim 9, wherein
the first color conversion layer of the first light emitting member includes first phosphors corresponding to the wavelength region of the first color, and
the first color conversion layer of the second light emitting member includes second phosphors corresponding to the wavelength region of the second color.

14. The display panel of claim 13, wherein
the first phosphors include at least one selected from the group of (Sr, Ca)AlSiN₃:Eu²⁺, K₂(Si, Ge, T1)F₆:Mn⁴⁺, Mg₄GeO₃F:Mn⁴⁺, and 3.5MgO·0.5MgF₂·GeO₂:Mn⁴⁺, and the second phosphors include at least one selected from the group of Beta-SiAlON:Eu²⁺, SrGa₂S₄:Eu²⁺, BaAlMg₁₀O₁₇:Eu²⁺, Mn²⁺, and (Lu,Y)₃(Al, Ga)₅O₁₂:Ce³⁺.

15. The display panel of claim 9, wherein the light emitting device of the first light emitting member and the light emitting device of the second light emitting member each emits light of a wavelength region lower than the wavelength region of the third color.

16. The display panel of claim 9, wherein
the light emitting device of the first light emitting member emits light of a wavelength region lower than the wavelength region of the third color, and
the light emitting device of the second light emitting member emits light of a wavelength region of the third color.

17. The display panel of claim 16, wherein the first color conversion layer of the second light emitting member includes phosphors converting the light of the wavelength region of the third color emitted from the light emitting device into light of the wavelength region of the second color.

18. The display panel of claim 17, wherein the phosphors of the first color conversion layer of the second light emitting member includes Beta-SiAlON:Eu²⁺.

19. The display panel of claim 9, wherein the light emitting device of the first light emitting member and the light emitting device of the second light emitting member each emits light of a wavelength region of the third color.

20. The display panel of claim 19, wherein
the first color conversion layer of the first light emitting member includes first phosphors converting the light of the wavelength region of the third color emitted from the light emitting device into light of the wavelength region of the first color, and
the first color conversion layer of the second light emitting member includes second phosphors converting the light of the wavelength region of the third color emitted from the light emitting device into light of the wavelength region of the second color.

21. The display panel according to claim 20, wherein
the first phosphors include (Sr, Ca)AlSiN₃:Eu²⁺ or K₂(Si, Ge, T1)F₆:Mn⁴⁺, and
the second phosphors include at least one selected from the group of Beta-SiAlON:Eu²⁺, SrGa₂S₄:Eu²⁺, (Lu, Y)₃(Al, Ga)₅O₁₂:Ce³⁺, BaAlMg₁₀O₁₇:Eu²⁺, Mn⁴⁺, and (Sr, Ba, Mg)₂SiO₄:Eu²⁺.

22. The display panel of claim 2, further comprising:
a protective layer disposed on the plurality of light emitting members and the bank; and
a color filter layer disposed on the protective layer, wherein
the color filter layer includes:
a first color filter corresponding to the first light emitting member;
a second color filter corresponding to the second light emitting member;
a third color filter corresponding to the third light emitting member; and
a light blocking member corresponding to the bank.

23. The display panel of claim 22, wherein
the protective layer includes an inorganic insulating material of SiO₂₋ₓ or SiO₂, and
x is 0, 1, or 2.

24. The display panel of claim 1, further comprising a transistor array disposed on the substrate, wherein
the transistor array includes:
at least one thin film transistor disposed on the substrate and corresponding to each of the plurality of emission areas;
a common line disposed on the substrate and extending in a direction corresponding to arrangement directions of the plurality of emission areas;
a planarization layer disposed on the at least one thin film transistor and the common line of each of the plurality of emission areas;
a pixel electrode disposed on the planarization layer in each of the plurality of emission areas; and
a common electrode disposed on the planarization layer in each of the plurality of emission areas, spaced apart from the pixel electrode, and electrically connected to the common line,
the bank is disposed on the planarization layer,
the pixel electrode is electrically connected to at least one of the at least one thin film transistor, and
a first electrode of the light emitting device is disposed on the pixel electrode, faces the pixel electrode, and is electrically connected to the pixel electrode in each of the plurality of emission areas.

25. The display panel of claim 24, wherein
the light emitting device includes a second electrode facing the first electrode, and
the second electrode of the light emitting device is electrically connected to the common electrode through a wire.

26. The display panel of claim 24, wherein
the light emitting device includes a second electrode disposed parallel to the first electrode,
the second electrode of the light emitting device faces the common electrode and is electrically connected to the common electrode through an extension electrode, and
the extension electrode is disposed between the common electrode and the second electrode.

27. The display panel of claim 1, wherein
the light scattering layer includes scatterers,
a diameter of each of the scatterers is in a range of about 10 nm to about 500 nm, and
the scatterers includes at least one selected from the group of titanium oxide (TiO₂), silicon oxide (SiO₂), aluminum oxide (Al₂O₃), and zirconium oxide (ZrO₂).

28. The display panel of claim 1, further comprising a reflective layer disposed on an edge of each of the plurality of emission areas and covering a sidewall of the bank.

29. The display panel of claim 28, wherein the reflective layer includes scatterers including at least one selected from the group of titanium oxide (TiO₂), silicon oxide (SiO₂), aluminum oxide (Al₂O₃), zirconium oxide (ZrO₂), and boron nitride (BN).
